(19) United States
(12) Patent Application Publication
(10) Pub. No.: US 2013/0122711 A1
(43) Pub. Date: May 16, 2013

(54) SYSTEM, METHOD AND APPARATUS FOR PLASMA SHEATH VOLTAGE CONTROL

(71) Applicants: Alexei Marakhtanov, San Jose, CA (US); Rajinder Dhindsa, San Jose, CA (US); Eric Hudson, San Jose, CA (US); Andrew D. Bailey, III, San Jose, CA (US)

(72) Inventors: Alexei Marakhtanov, San Jose, CA (US); Rajinder Dhindsa, San Jose, CA (US); Eric Hudson, San Jose, CA (US); Andrew D. Bailey, III, San Jose, CA (US)

(21) Appl. No.: 13/294,053

(22) Filed: Nov. 10, 2011

(51) Int. Cl. H01L 21/3065; C23F 1/08

(52) U.S. Cl. 438/711; 156/345.24; 156/345.26; 257/E21.218

(57) ABSTRACT

A system, method and apparatus for increasing an energy level of the ions emitted from a plasma include a plasma chamber, including a top electrode and a bottom electrode, a multiple RF sources, at least one of the RF sources being coupled to the bottom electrode. A phase locking circuit is coupled to at least two of the RF sources hereafter designated the first RF source and the second RF source. A controller is coupled to the plasma chamber, each of the RF sources and the phase locking circuit. The controller including operating system software, multiple logic circuits and a process recipe.

### CROSS REFERENCE TO RELATED APPLICATIONS

This application is related to U.S. patent application Ser. No. 13/188,421 filed on Jul. 21, 2011 and entitled “Negative Ion Control for Dielectric Etch,” which is incorporated herein by reference in its entirety.

### BACKGROUND

The present invention relates generally to plasma processing, and more particularly, to systems, methods and apparatus for controlling plasma sheath voltage.

Manufacturing integrated circuits includes immersing semiconductor substrates (wafers) containing regions of doped silicon into chemically-reactive plasmas, where the submicron device features (e.g., transistors, capacitors, etc.) are etched onto the surface layer. One or more back-end insulating (dielectric) layers are then built on top of the first layer. Holes (e.g., vias) and trenches are etched into the layers for placement of the conductive interconnections.

SiO₂ is a common dielectric used in integrated circuits manufacturing. The etching plasmas used on SiO₂ layers typically include fluorocarbon gases such as carbon tetrafluoride CF₄ and octafluorocyclobutane (C—C₄F₈), along with argon (Ar) and oxygen (O₂) gases. As used herein, “plasma” refers to those gases in which the constituent atoms and molecules have been partially or wholly ionized.

Capacitive radio frequency (RF) power coupling is often used for striking and sustaining the plasma because of the low dissociation rates obtained, favoring larger passivating molecules and high ion energies at the surface. To obtain independent control of the ion energy and the ion flux to the silicon substrate, dual frequency capacitive discharges (DF-CCP) are sometimes used.

Etching the semiconductor wafer is often performed by positive ions when the positive ions escape from the plasma and strike the feature to be etched. The etch rate of the plasma ions is a function of the energy imparted to the plasma ions by the plasma. Typically, increases in energy are produced by increasing the RF power applied to the plasma.

Unfortunately, the increased RF power can also cause arcing within the plasma chamber, e.g., arcing from one portion of the plasma chamber to another portion of the plasma chamber and/or the semiconductor wafer. This arcing can damage the plasma chamber and the semiconductor wafer.

The increased RF power also requires more power supplied to the plasma chamber (i.e., a larger RF generator and increased demand on utility power source). The increased RF power also requires additional cooling capacity which further increases operating costs, system space requirements and demands for utility power source.

In view of the foregoing, there is a need for systems, methods and apparatus for controlling plasma sheath voltage to increase the energy level of the plasma ions.

### SUMMARY

Broadly speaking, the present invention fills these needs by providing a systems, methods and apparatus for controlling plasma sheath voltage to increase the energy level of the plasma ions. It should be appreciated that the present invention can be implemented in numerous ways, including as a process, an apparatus, a system, computer readable media, or a device. Several inventive embodiments of the present invention are described below.

One embodiment provides a phase-locked plasma chamber system including a plasma chamber, including a top electrode and a bottom electrode, a multiple RF sources, at least one of the RF sources being coupled to the bottom electrode. A phase locking circuit is coupled to at least two of the RF sources hereafter designated the first RF source and the second RF source. A controller is coupled to the plasma chamber, each of the RF sources and the phase locking circuit. The controller including operating system software, multiple logic circuits and a process recipe.

A ground potential coupled to the top electrode. The top electrode and the bottom electrode can be symmetrical. The top electrode and the bottom electrode can be asymmetrical.

The first RF source and the second RF source are coupled to the phase locking circuit and have corresponding outputs coupled to the bottom electrode. A third RF source can be coupled to the bottom electrode. The third RF source can be coupled to the top electrode. The first RF source can have a corresponding output coupled to the bottom electrode and the second RF source can have a corresponding output coupled to the top electrode.

The top electrode can include a contoured lower surface including a raised peripheral ring extending toward an outer periphery of the bottom electrode. The contoured lower surface can also include a tapered ring portion around an outer periphery of the raised peripheral ring. The plasma chamber can also include a plasma confinement structure. The plasma confinement structure can include at least one plasma confinement ring.

Another embodiment provides a method of increasing an energy level of the ions emitted from a plasma including injecting a process gas into the plasma chamber, phase-locking a first RF signal and a second RF signal, wherein the second RF signal is a second harmonic of the first RF signal, coupling the phase-locked first RF signal and second RF signal to the plasma chamber, igniting a plasma in the plasma chamber, ejecting plasma ions from a lower plasma sheath with an increased energy when the phase-locked first RF signal and second RF signal peaks coincide.

The increased energy plasma ions can react with a surface of a semiconductor wafer on the bottom electrode of the plasma chamber. A third RF signal can be coupled to the plasma chamber, wherein the third RF signal can be coupled to a top electrode in the plasma chamber and the phase-locked first RF signal and second RF signal can be coupled to a bottom electrode in the plasma chamber. Alternatively, the first RF signal and the third RF signal can be coupled to a bottom electrode in the plasma chamber and the second RF signal can be coupled to a bottom electrode in the plasma chamber. The phase-locked first RF signal and second RF signal and the third RF signal can be coupled to the bottom electrode in the plasma chamber.

Yet another embodiment provides a phase-locked plasma chamber system including a plasma chamber, including a top electrode and a bottom electrode, a multiple RF sources, at least one of the RF sources being coupled to the bottom electrode. A phase locking circuit is coupled to at least two of the RF sources hereafter designated the first RF source and the second RF source. A controller is coupled to the plasma chamber, each of the RF sources and the phase locking circuit. The controller including operating system software, multiple logic circuits and a process recipe. The operating system and logic circuits can include logic for injecting a process gas into the plasma chamber, logic for phase-locking a first RF signal and a second RF signal, wherein the second RF signal is a second harmonic of the first RF signal, logic for coupling the phase-locked first RF signal and second RF signal to the plasma chamber, logic for igniting a plasma in the plasma chamber, logic for ejecting plasma ions from a lower plasma sheath with an increased energy when the phase-locked first RF signal and second RF signal peaks coincide.

Other aspects and advantages of the invention will become apparent from the following detailed description, taken in conjunction with the accompanying drawings, illustrating by way of example the principles of the invention.

### BRIEF DESCRIPTION OF THE DRAWINGS

The present invention will be readily understood by the following detailed description in conjunction with the accompanying drawings.

FIG. 1A is a simplified schematic diagram of a phase-locked, symmetrical plasma chamber system, in accordance with embodiments of the present invention.

FIG. 1B is a voltage graph of the RF signals applied to the phase-locked, symmetrical plasma chamber system, in accordance with embodiments of the present invention.

FIG. 2A is a simplified schematic diagram of a phase-locked, asymmetrical plasma chamber system, in accordance with embodiments of the present invention.

FIG. 2B is a voltage graph of the RF signals applied to the plasma chamber system, in accordance with embodiments of the present invention.

FIG. 2C is a voltage graph of a wafer sheath potential with 90 degree phase shift, in accordance with embodiments of the present invention.

FIG. 2D is voltage graph of a wafer sheath potential with 0 degree phase shift (e.g., phase-locked), in accordance with embodiments of the present invention.

FIGS. 2E and 2F are graphs 260, 270 of the ion energy corresponding to wafer sheath potentials shown in FIGS. 2C and 2D, respectively, in accordance with embodiments of the present invention.

FIGS. 3A and 3B are alternative embodiments of phase-locked, asymmetrical electrode configurations for plasma chambers, in accordance with embodiments of the present invention.

FIG. 4 is a flowchart diagram that illustrates the method operations performed in increasing an energy level of the ions emitted from a plasma using a phase-locked plasma chamber, in accordance with embodiments of the present invention.

FIGS. 5A-5F are alternative embodiments of phase-locked, asymmetrical electrode configurations for plasma chambers, in accordance with embodiments of the present invention.

FIG. 6 is a block diagram of an exemplary computer system for carrying out the processing according to embodiments of the invention.

FIG. 7 is a block diagram of an integrated system including one or more of the plasma processing chambers, in accordance with embodiments of the present invention.

### DETAILED DESCRIPTION

Several exemplary embodiments for systems, methods and apparatus for controlling plasma sheath voltage to increase the energy level of the plasma ions will now be described. It will be apparent to those skilled in the art that the present invention may be practiced without some or all of the specific details set forth herein.

One approach to achieve higher ion energy is to use higher RF power. Another approach includes increasing ion energy through manipulating the electrode area ratio. For example, the physical ground area can be increased by introducing ACC (FLEX) and ACC+(FLEX+). The physical limit of ACC+ is determined by: (ACC+OD˜chamber ID).

As noted above, increased RF power also increases the power consumption and power dissipation (e.g., cooling) and wear rate of the plasma chamber. Cooling the top electrode and/or the chamber walls provides temperature control of plasma chamber at high RF powers.

Another approach to provide increased ion energy with reduced (compared to FLEX+13 kW) RF power and also reduces RF power dissipation in UE and reduces ground area/volume to reduce cost and improve cleaning efficiency (e.g., silicon high aspect ratio contact (Si HARC) etch). Increased ion energy can be achieved using a electrical sheath asymmetry effect combined with controlling a relative phase (e.g., phase locking) between applied fundamental RF frequency (F) and the second harmonic of the applied fundamental RF frequency (2F).

Phase locking the applied fundamental RF frequency (F) and the second harmonic of the applied fundamental RF frequency (2F) can also be used to control wafer bias in a geometrically symmetric system. Wafer bias is linearly proportional to phase. By way of example, where F=13.56 MHz and 2F=27.17 MHz, no significant change in plasma density observed with phase.

In another example where F=2 MHz and 2F=4 MHz, with 1000V RF amplitude, the selected Vdc can be reversed between top and bottom electrodes.

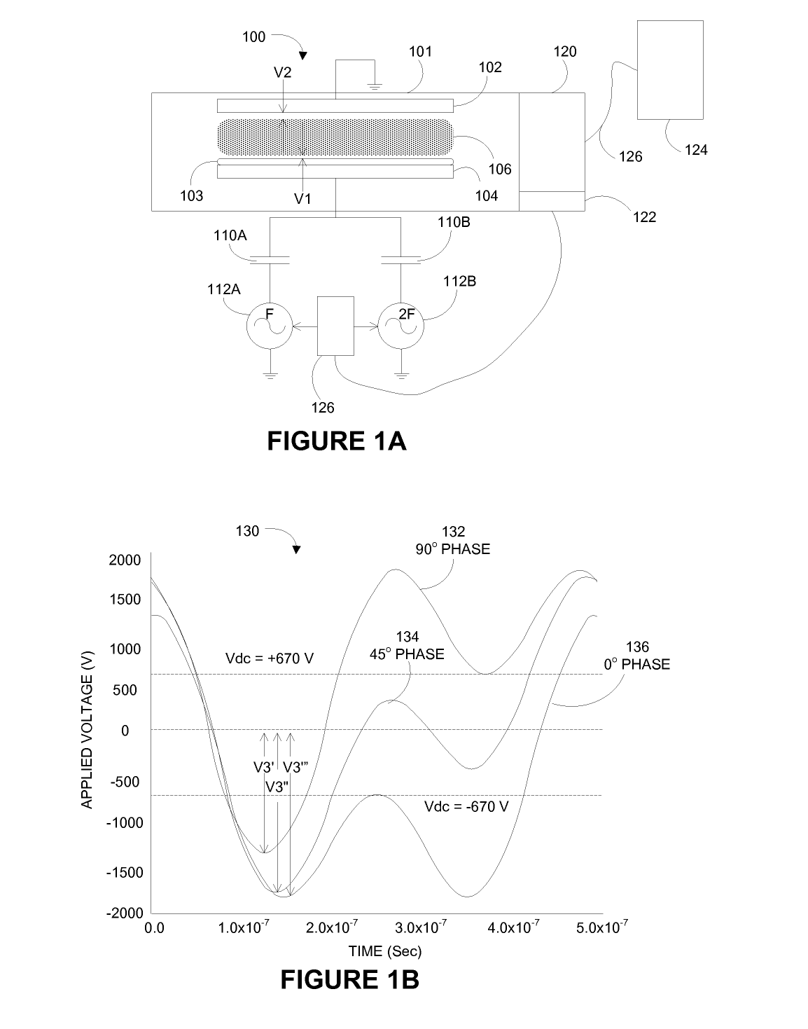

FIG. 1A is a simplified schematic diagram of a phase-locked, symmetrical plasma chamber system 100, in accordance with embodiments of the present invention. FIG. 1B is a voltage graph of the RF signals applied to the phase-locked, symmetrical plasma chamber system 100, in accordance with embodiments of the present invention. The plasma chamber system 100 includes a plasma chamber 101, two RF sources 112A, 112B, coupled to the bottom electrode 104, a grounded top electrode 102 and a plasma 106 formed between the electrodes 102, 104. A phase locking circuit 126 is coupled to the two RF sources 112A, 112B and allows phase locking thereof. A controller 120 is also included in the plasma chamber system 100. The controller includes operating system software and logic circuits and a recipe (e.g. operational sequences and set points). The controller 120 can also be coupled to a centralized monitoring and control system 124 by a network 126.

A semiconductor wafer 104 is supported on the bottom electrode 104. The plasma chamber system 100 is symmetrical because the area of the top electrode 102 is substantially equal to the area of the bottom electrode 104.

The two RF sources 112A, 112B produce 2 MHz and 4 MHz, respectively. A phase locking circuit 126 is coupled to both of the two RF sources 112A, 112B. The phase locking circuit 126 can selectively lock the phases of the respective RF outputs.

Then the RF voltage applied to wafer is given by the following relationship:

V(t)=Vdc+Vrf[cos(φ+0)+cos(2φ)]

Where Vdc is a dc self-bias, Vrf is an amplitude of applied RF voltage, in this instance same for both 2 and 4 MHz, and θ is the phase angle between applied RF signals.

Referring now to FIG. 1B, graph 132 is a composite graph of the bottom electrode 104 voltage when the first RF signal source 112A is 90 degrees out of phase from the second RF signal source 112B. As shown in graph 132 the bottom electrode 104 voltage has a maximum magnitude V3′ peak. Graph 134 is a composite graph of the bottom electrode 104 voltage when the first RF signal source 112A is 45 degrees out of phase from the second RF signal source 112B. As shown in graph 134 the bottom electrode 104 voltage has a maximum magnitude V3″ peak.-Graph 136 a composite graph of the bottom electrode 104 voltage when the first RF signal source 112A is phase locked (e.g., 0 degrees out of phase) with the second RF signal source 112B. As shown in graph 136 the bottom electrode 104 voltage has a maximum magnitude V3′″ peak thus showing that V3′<V3″<V3′″ and that the phase locked first 112A and second 112B RF signal sources provide a maximum magnitude V3′″ peak. This maximum magnitude V3′″ peak also determines the instantaneous peak wafer sheath potential V1 as will be described in more detail below. Moreover, each of the three instances provide different DC bias on the powered electrode, that can be easily selected and controlled by selecting and controlling the phase angle between applied RF signals.

As the plasma chamber system 100 is a geometrically symmetric system wafer bias is linearly proportional to phase.

Where F=2 and 2F=4 MHz and with 1000V RF amplitude the wafer bias voltage on the electrodes 102, 104 can be reversed at certain periods of the RF signal. V1 is the wafer sheath potential (e.g., a voltage potential between the lower plasma sheath and the wafer 103 on the bottom electrode 104). V2 is the upper sheath voltage (e.g., a voltage potential between the upper plasma sheath and the top electrode 102). The magnitude of V1 determines the magnitude of the ion energy.

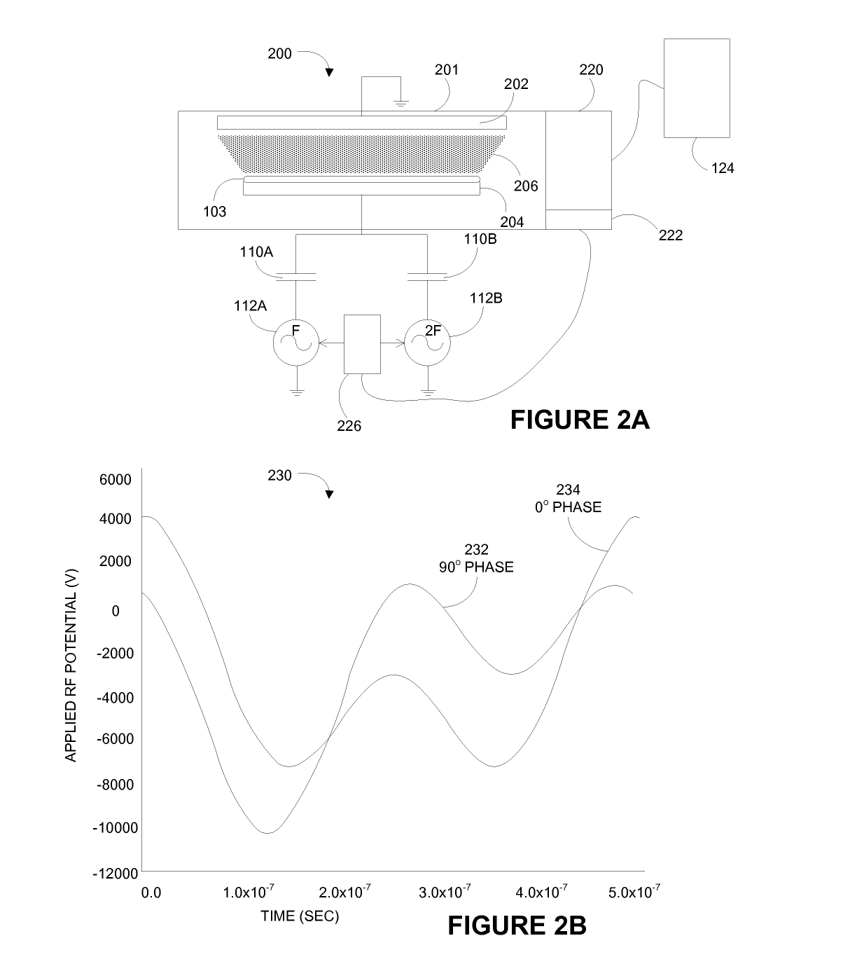

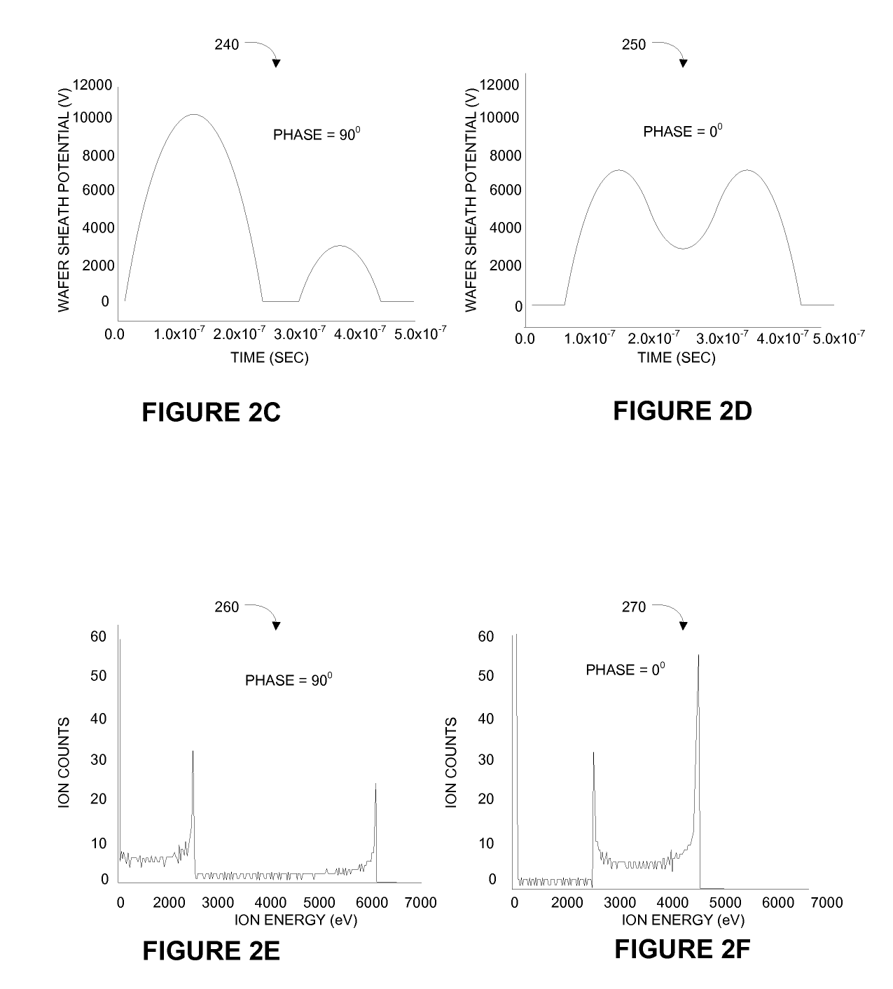

FIG. 2A is a simplified schematic diagram of a phase-locked, asymmetrical plasma chamber system 200, in accordance with embodiments of the present invention. The plasma chamber system 200 is a geometrically asymmetric capacitive system because the electrodes 202 and 204 are not substantially equal in area. As a result the plasma sheath has a corresponding area according to the respective electrodes 202, 204.

FIG. 2B is voltage graphs 230 of the RF signals 232, 234 applied to the plasma chamber system 200, in accordance with embodiments of the present invention. FIGS. 2C and 2D are voltage graphs 240, 250 of a wafer sheath potential V1 applied to the phase-locked, asymmetrical plasma chamber system 200, in accordance with embodiments of the present invention. The RF signals F1, F2 are applied 90 degrees out of phase in graph 232 and 240. The RF signals F1, F2 are phase locked (e.g., applied 0 degrees out of phase) in graphs 234 and 250. With F=2 MHz and 2F=4 MHz and RF sources 112A, 112B are phase locked in graphs 234 and 250. An example fixed bias of −3 kVdc is applied to the semiconductor wafer 103.

FIGS. 2E and 2F are graphs 260, 270 of the ion energy corresponding to wafer sheath potentials shown in FIGS. 2C and 2D, respectively, in accordance with embodiments of the present invention.

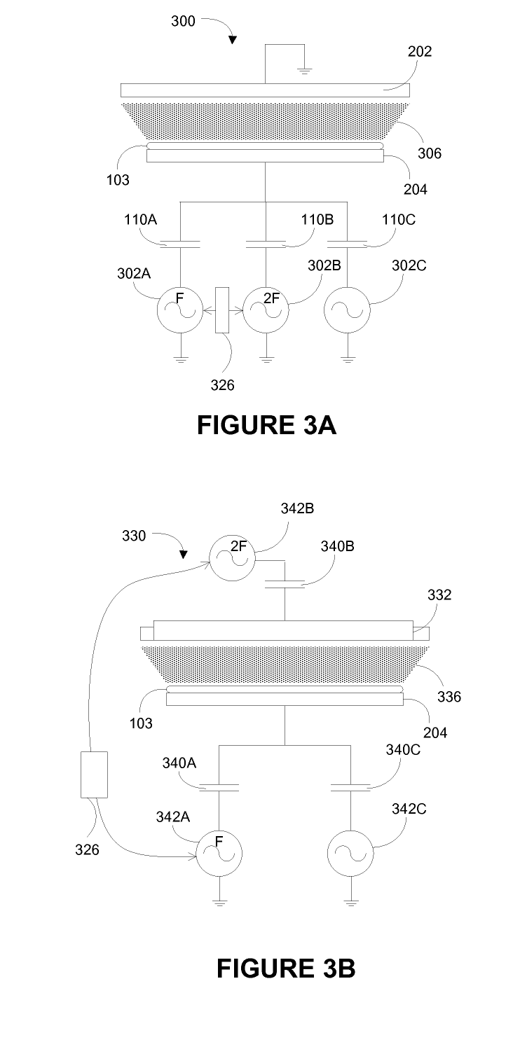

FIGS. 3A and 3B are alternative embodiments of a phase-locked, asymmetrical electrode configurations 300, 330 for plasma chambers, in accordance with embodiments of the present invention. As shown in FIG. 3A, three RF signal sources 302A-302C are coupled to the bottom electrode 204. RF signal sources 302A and 302B are coupled to a phase locking circuit 326. RF signal sources 302A and 302B output phase locked signals F and 2F (e.g., second harmonic of F), respectively.

As shown in FIG. 3B, RF signal sources 342A and 342C are coupled to the bottom electrode 204. A third RF signal source 342B is coupled to the top electrode 332. RF signal sources 342A and 342B are coupled to a phase locking circuit 326. RF signal sources 342A and 342B output phase locked signals F and 2F (e.g., second harmonic of F), respectively.

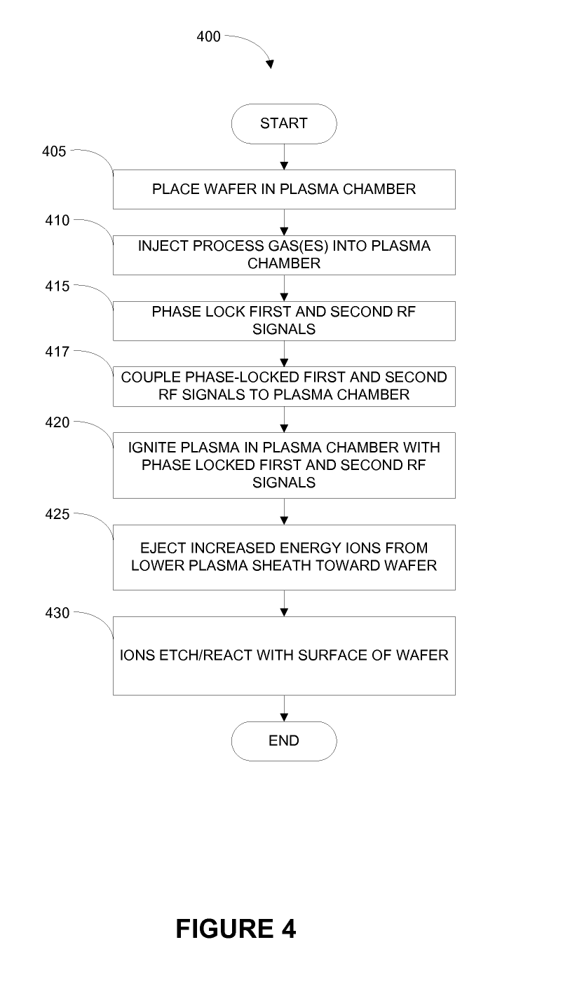

FIG. 4 is a flowchart diagram that illustrates the method operations 400 performed in increasing an energy level of the ions emitted from a plasma using a phase-locked plasma chamber, in accordance with embodiments of the present invention. The operations illustrated herein are by way of example, as it should be understood that some operations may have sub-operations and in other instances, certain operations described herein may not be included in the illustrated operations. With this in mind, the method and operations 400 will now be described.

In an operation 405, a semiconductor wafer 103 is placed in the plasma chamber. The plasma chamber can be symmetrical or asymmetrical. A process gas is injected into the plasma chamber in an operation 410.

In an operation 415, a first RF signal and a second RF signal are phase locked. The second RF signal is a second harmonic of the first RF signal. In an operation 417 the phase-locked first RF signal and second RF signal are coupled to the plasma chamber. The phase-locked first RF signal and second RF signal can be coupled to the plasma chamber in a number of implementations. By way of example, the phase-locked first RF signal and second RF signal can both be coupled to the bottom electrode 104. In another example, the phase-locked first RF signal can be coupled to the bottom electrode 104 and the second RF signal can be coupled to the top electrode 102. In yet a third example, a third RF signal can be coupled to the plasma chamber, wherein the third RF signal is coupled to the top electrode 102 the phase-locked first RF signal and second RF signal are coupled to the bottom electrode 104. In still another example, the first RF signal and the third RF signal can be coupled to a bottom electrode 104 and the second RF signal can be coupled to the bottom electrode 104. In another example, the phase-locked first RF signal and second RF signal and the third RF signal are coupled to the bottom electrode 104. The foregoing are merely exemplary implementations and it should be understood that the first, second and third RF signals can be coupled to the plasma chamber in any possible configuration.

In an operation 420, a plasma is ignited in the plasma chamber.

In an operation 425, plasma ions are ejected from the lower plasma sheath with an increased energy when the phase locked first RF signal and second RF signal peaks coincide. The increased energy plasma ions can more aggressively react with the surface of the semiconductor wafer 103 in an operation 430 and the method operations can end.

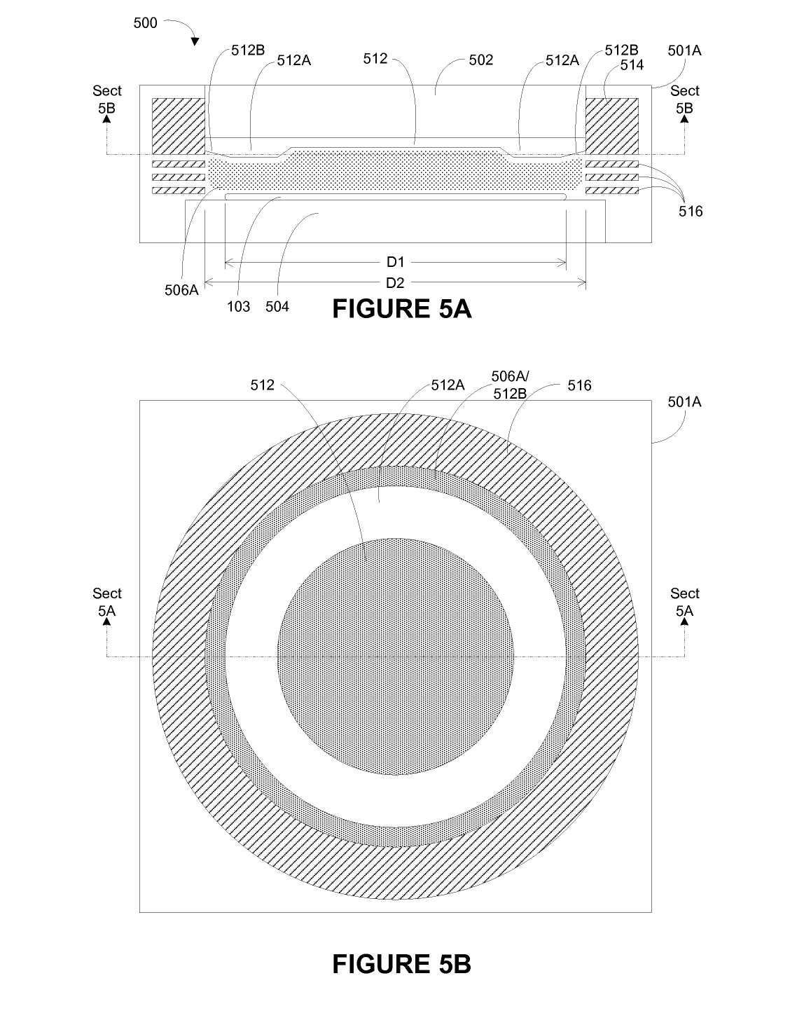

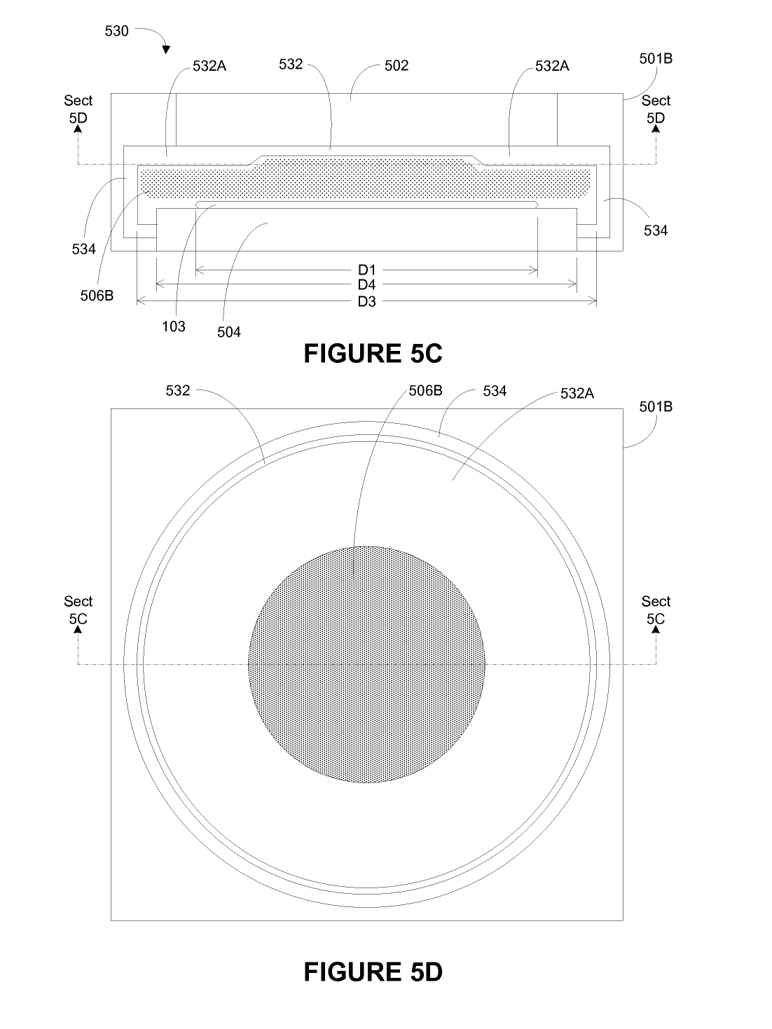

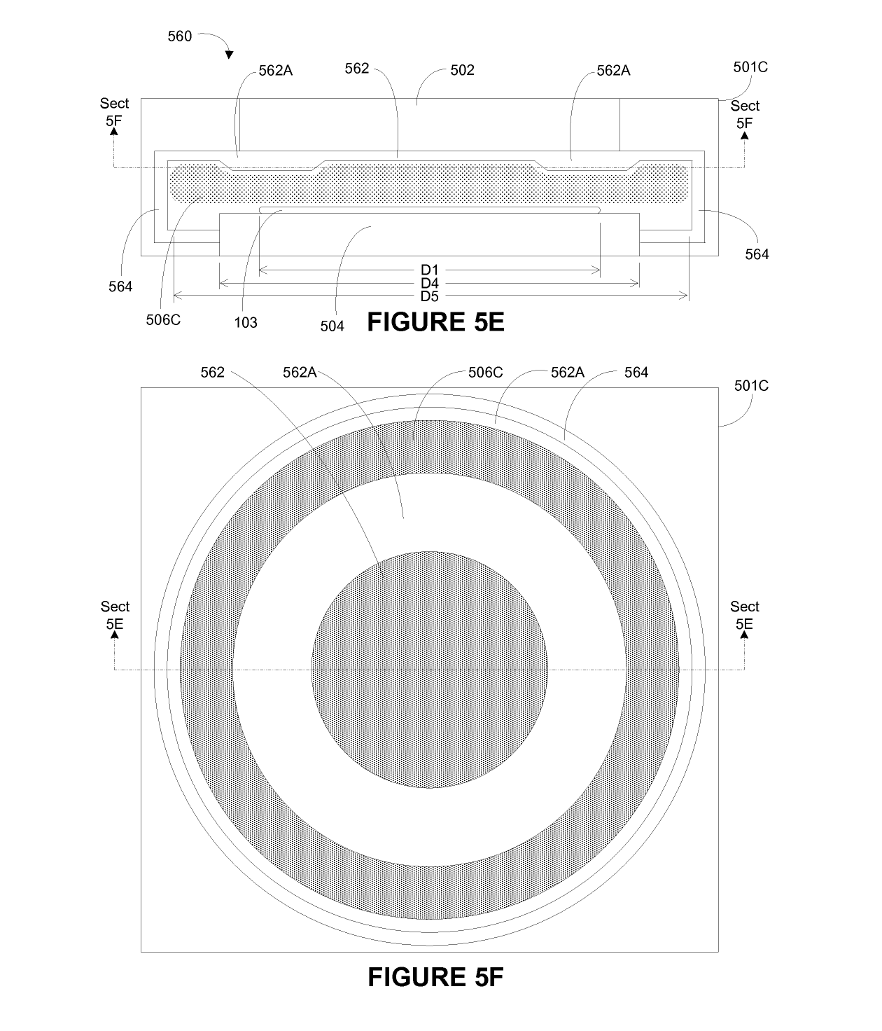

FIGS. 5A-5F are alternative embodiments of a phase-locked, asymmetrical electrode configurations 500, 530, 560 for plasma chambers, in accordance with embodiments of the present invention. Plasma chamber 500 includes plasma confinement rings 514, 516 that confine the plasma 506A over the semiconductor wafer 103. The upper electrode 502 has a contoured lower surface 512. The contoured lower surface 512 includes a raised peripheral ring 512A that extends toward the outer periphery of the bottom electrode 504 and the outer periphery of the semiconductor wafer 103 and further concentrates the plasma 506A near outer periphery of the semiconductor wafer. The contoured lower surface 512 further includes a tapered ring portion 512B around an outer periphery of the raised peripheral ring 512A. The tapered ring portion 512B allows the plasma 506A to expand toward the top electrode 502 outside the perimeter of the semiconductor wafer 103. The plasma confinement rings 514, 516 have an internal diameter D2 that is greater than the diameter D1 of the semiconductor wafer 103. The contoured lower surface 512 is thus forms an upper electrode that is asymmetrical in area to the bottom electrode 504.

Plasma chamber 530 includes a plasma confinement 534 that confines the plasma 506B over the semiconductor wafer 103. The upper electrode 502 has a contoured lower surface 532 that is physically and electrically coupled to the plasma confinement structure 534. The plasma confinement structure 534 can include a solid structure as shown in FIG. 5C. The plasma confinement structure 534 can include confinement rings 516 as shown in FIG. 5A. The plasma confinement structure 534 can include a combination of the solid structure as shown in FIG. 5C and the confinement rings 516 as shown in FIG. 5A. The contoured lower surface 532 includes a raised peripheral ring 532A that extends toward the outer periphery of the semiconductor wafer 103 and further concentrates the plasma 506B near outer periphery of the semiconductor wafer. The plasma confinement structure 534 has an internal diameter D3 that is greater than the diameter D1 of the semiconductor wafer 103. The contoured lower surface 532 and the plasma confinement structure 534 thus forms an upper electrode that is in area asymmetrical to the bottom electrode 504.

Plasma chamber 560 includes a plasma confinement structure 564 that confines the plasma 506C over the semiconductor wafer 103. The plasma confinement structure 564 can include a solid structure as shown in FIG. 5C and FIG. 5E. The plasma confinement structure 564 can include confinement rings 516 as shown in FIG. 5A. The plasma confinement structure 564 can include a combination of the solid structure as shown in FIGS. 5C and 5E and the confinement rings 516 as shown in FIG. 5A. The upper electrode 502 has a contoured lower surface 562 that is physically and electrically coupled to the plasma confinement 544. The contoured lower surface 562 includes a raised peripheral ring 562A that extends toward the outer periphery of the semiconductor wafer 103 and further concentrates the plasma 506C near outer periphery of the semiconductor wafer. The plasma confinement structure 564 has an internal diameter D5 that is greater than the diameter D1 of the semiconductor wafer 103 and greater than the diameter D4 of the bottom electrode. The contoured lower surface 562 has an outer periphery portion 562B that is wider than the diameter D1 of the semiconductor wafer 103, thus allowing the plasma 506C to expand vertically and horizontally beyond the diameter D1 of the semiconductor wafer 103. The contoured lower surface 562 and the plasma confinement structure 564 thus forms an upper electrode that is asymmetrical in area to the bottom electrode 504.

With the above embodiments in mind, it should be understood that the invention may employ various computer-implemented operations involving data stored in computer systems. These operations are those requiring physical manipulation of physical quantities. Usually, though not necessarily, these quantities take the form of electrical or magnetic signals capable of being stored, transferred, combined, compared, and otherwise manipulated. Further, the manipulations performed are often referred to in terms, such as producing, identifying, determining, or comparing.

Any of the operations described herein that form part of the invention are useful machine operations. The invention also relates to a device or an apparatus for performing these operations. The apparatus may be specially constructed for the required purposes, or it may be a general purpose computer selectively activated or configured by a computer program stored in the computer. In particular, various general purpose machines may be used with computer programs written in accordance with the teachings herein, or it may be more convenient to construct a more specialized apparatus to perform the required operations. An exemplary structure for the invention is described below.

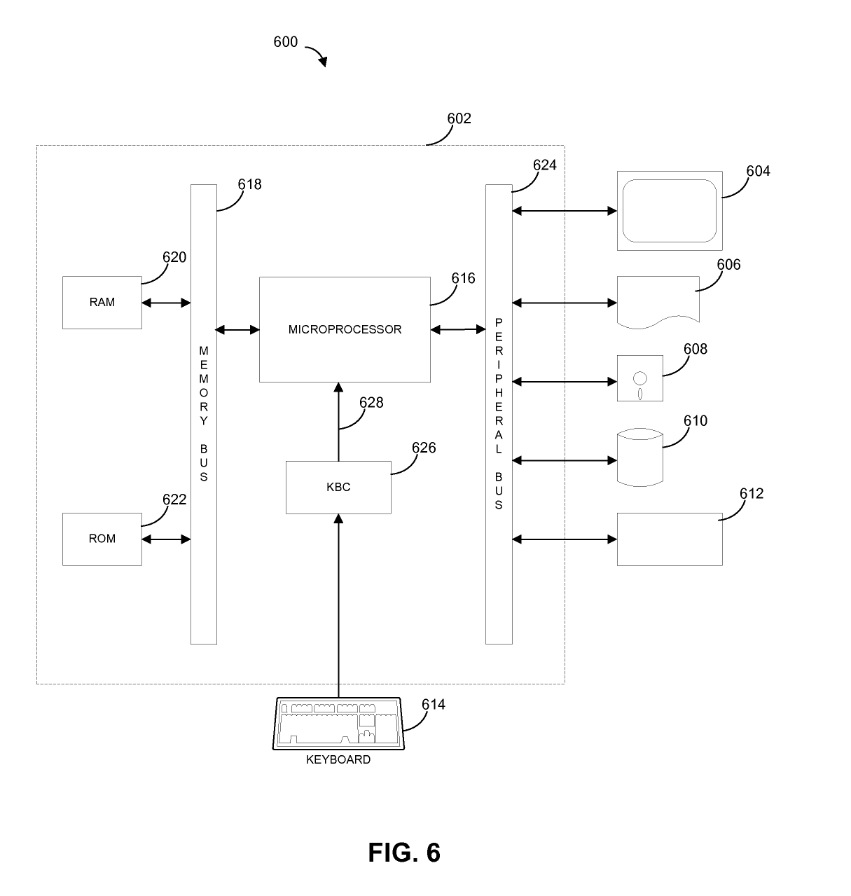

FIG. 6 is a block diagram of an exemplary computer system 600 for carrying out the processing according to embodiments of the invention. The computer system 600 can be used for the controller 120 and/or the monitoring system 124. The computer system 600 includes a digital computer 602, a display screen (or monitor) 604, a printer 606, a floppy disk/optical/flash drive 608, a hard disk drive 610, a network interface 612, and a keyboard 614. The digital computer 602 includes a microprocessor 616, a memory bus 618, random access memory (RAM) 620, read only memory (ROM) 622, a peripheral bus 624, and a keyboard controller (KBC) 626. The digital computer 602 can be a personal computer (such as an IBM compatible personal computer, a Macintosh computer or Macintosh compatible computer), a workstation computer (such as a Sun Microsystems or Hewlett-Packard workstation), or some other type of computer.

The microprocessor 616 is a general purpose digital processor, which controls the operation of the computer system 600. The microprocessor 616 can be a single-chip processor or can be implemented with multiple components. Using instructions retrieved from memory, the microprocessor 616 controls the reception and manipulation of input data and the output and display of data on output devices.

The memory bus 618 is used by the microprocessor 616 to access the RAM 620 and the ROM 622. The RAM 620 is used by the microprocessor 616 as a general storage area and as scratch-pad memory, and can also be used to store input data and processed data. The ROM 622 can be used to store instructions or program code followed by the microprocessor 616 as well as other data.

The peripheral bus 624 is used to access the input, output, and storage devices used by the digital computer 602. In the described embodiment, these devices include the display screen 604, the printer device 606, the floppy disk/optical/flash drive 608, the hard disk drive 610, and the network interface 612. The keyboard controller 626 is used to receive input from keyboard 614 and send decoded symbols for each pressed key to microprocessor 616 over bus 628.

The display screen 604 is an output device that displays images of data provided by the microprocessor 616 via the peripheral bus 624 or provided by other components in the computer system 600. The printer device 606, when operating as a printer, provides an image on a sheet of paper or a similar surface. Other output devices such as a plotter, typesetter, etc. can be used in place of, or in addition to, the printer device 606.

The floppy disk/optical/flash drive 608 and the hard disk drive 610 can be used to store various types of data. The floppy disk/optical/flash drive 608 facilitates transporting such data to other computer systems, and hard disk drive 610 permits fast access to large amounts of stored data.

The microprocessor 616 together with an operating system operate to execute computer code and produce and use data. The computer code and data may reside on the RAM 620, the ROM 622, or the hard disk drive 610. The computer code and data could also reside on a removable program medium and loaded or installed onto the computer system 600 when needed. Removable program media include, for example, CD-ROM, PC-CARD, floppy disk, flash memory, optical media and magnetic tape.

The network interface 612 is used to send and receive data over a network connected to other computer systems. An interface card or similar device and appropriate software implemented by the microprocessor 616 can be used to connect the computer system 600 to an existing network and transfer data according to standard protocols (e.g., LAN, WAN, wireless, internet, etc.).

The keyboard 614 is used by a user to input commands and other instructions to the computer system 600. Other types of user input devices can also be used in conjunction with the present invention. For example, pointing devices such as a computer mouse, a track ball, a stylus, or a tablet can be used to manipulate a pointer on a screen of a general-purpose computer.

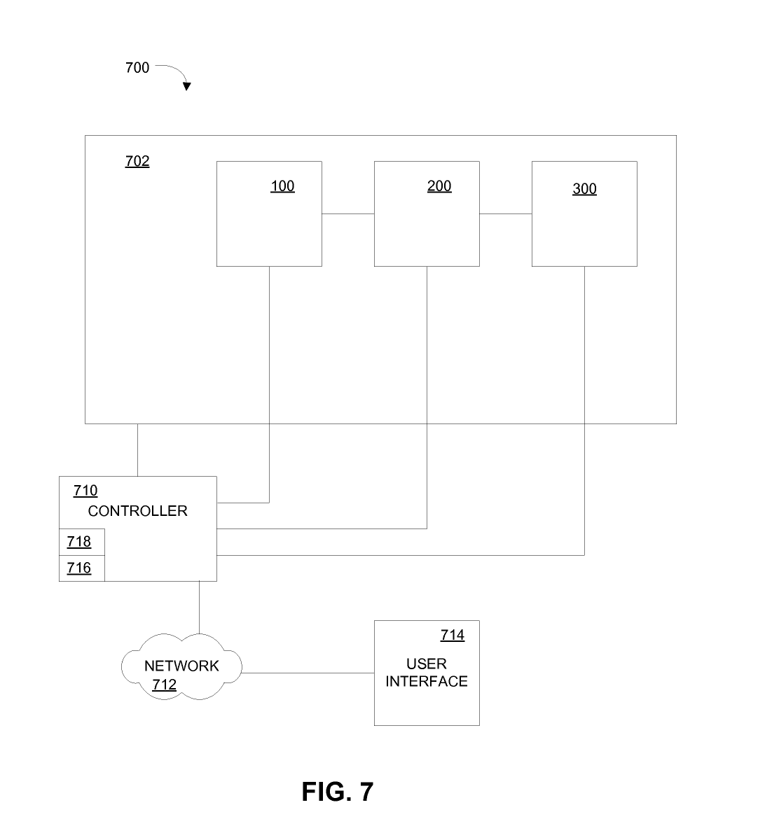

FIG. 7 is a block diagram of an integrated system 700 including one or more of the plasma processing chambers 100, 200, 300, 500, in accordance with embodiments of the present invention. The integrated system 700 includes the one or more of the plasma processing chambers 100, 200, 300, 500, and an integrated system controller 710 coupled to the processing chamber(s). The monitoring/control system 124 can be part of the integrated system controller 710. The integrated system controller 710 includes or is coupled to (e.g., via a wired or wireless network 712) a user interface 714. The user interface 714 provides user readable outputs and indications and can receive user inputs and provides user access to the integrated system controller 710.

The integrated system controller 710 can include a special purpose computer or a general purpose computer. The integrated system controller 710 can execute computer programs 716 to monitor, control and collect and store data 718 (e.g., performance history, analysis of performance or defects, operator logs, and history, etc.) for the plasma chamber(s). By way of example, the integrated system controller 710 can adjust the operations of the plasma chamber(s) and/or the components therein (e.g., the edge confinement ring, pressures, flow rates, bias signals, loading and unloading of the substrate 102, etc.) if data collected dictates an adjustment to the operation thereof.

The invention can also be embodied as computer readable code and/or logic on a computer readable medium. The computer readable medium is any data storage device that can store data which can thereafter be read by a computer system. Examples of the computer readable medium include hard drives, network attached storage (NAS), logic circuits, read-only memory, random-access memory, CD-ROMs, CD-Rs, CD-RWs, magnetic tapes, and other optical and non-optical data storage devices. The computer readable medium can also be distributed over a network coupled computer systems so that the computer readable code is stored and executed in a distributed fashion.

It will be further appreciated that the instructions represented by the operations in the above figures are not required to be performed in the order illustrated, and that all the processing represented by the operations may not be necessary to practice the invention. Further, the processes described in any of the above figures can also be implemented in software stored in any one of or combinations of the RAM, the ROM, or the hard disk drive.

Although the foregoing invention has been described in some detail for purposes of clarity of understanding, it will be apparent that certain changes and modifications may be practiced within the scope of the appended claims. Accordingly, the present embodiments are to be considered as illustrative and not restrictive, and the invention is not to be limited to the details given herein, but may be modified within the scope and equivalents of the appended claims.

What is claimed is:

1. A phase-locked plasma chamber system comprising:
a plasma chamber, including a top electrode and a bottom electrode;
a plurality of RF sources, at least one of the plurality of RF sources being coupled to the bottom electrode;
a phase locking circuit coupled to at least two of the plurality of RF sources hereafter designated the first RF source and the second RF source; and
a controller coupled to the plasma chamber, each of the plurality of RF sources and the phase locking circuit, the controller including:
operating system software;
a plurality of logic circuits; and
a process recipe.

2. The system of claim 1, wherein a ground potential coupled to the top electrode.

3. The system of claim 1, wherein the top electrode and the bottom electrode are symmetrical.

4. The system of claim 1, wherein the top electrode and the bottom electrode are asymmetrical.

5. The system of claim 1, wherein the first RF source and the second RF source are coupled to the phase locking circuit and have corresponding outputs coupled to the bottom electrode.

6. The system of claim 5, wherein a third one of the plurality of RF sources is coupled to the bottom electrode.

7. The system of claim 5, wherein a third one of the plurality of RF sources is coupled to the top electrode.

8. The system of claim 1, wherein the first RF source has a corresponding output coupled to the bottom electrode and the second RF source has a corresponding output coupled to the top electrode.

9. The system of claim 8, wherein a third one of the plurality of RF sources is coupled to the bottom electrode.

10. The system of claim 8, wherein a third one of the plurality of RF sources is coupled to the top electrode.

11. The system of claim 1, wherein the top electrode includes a contoured lower surface including a raised peripheral ring extending toward an outer periphery of the bottom electrode.

12. The system of claim 1, wherein the top electrode includes a contoured lower surface including a raised peripheral ring extending toward an outer periphery of the bottom electrode and a tapered ring portion around an outer periphery of the raised peripheral ring.

13. The system of claim 1, further comprising a plasma confinement structure.

14. The system of claim 1, further comprising a plasma confinement structure including at least one plasma confinement ring.

15. A method of increasing an energy level of the ions emitted from a plasma comprising:
injecting a process gas into the plasma chamber;
phase-locking a first RF signal and a second RF signal, wherein the second RF signal is a second harmonic of the first RF signal;
coupling the phase-locked first RF signal and second RF signal to the plasma chamber;
igniting a plasma in the plasma chamber;
ejecting plasma ions from a lower plasma sheath with an increased energy when the phase-locked first RF signal and second RF signal peaks coincide.

16. The method of claim 15, wherein the increased energy plasma ions react with a surface of the semiconductor wafer.

17. The method of claim 15, further comprising coupling a third RF signal to the plasma chamber, wherein the third RF signal is coupled to a top electrode in the plasma chamber and wherein the phase-locked first RF signal and second RF signal are coupled to a bottom electrode in the plasma chamber.

18. The method of claim 15, further comprising coupling a third RF signal to the plasma chamber, wherein the first RF signal and the third RF signal are coupled to a bottom electrode in the plasma chamber and wherein the second RF signal is coupled to a bottom electrode in the plasma chamber.

19. The method of claim 15, further comprising coupling a third RF signal to the plasma chamber, wherein the phase-locked first RF signal and second RF signal and the third RF signal are coupled to a bottom electrode in the plasma chamber.

20. A phase-locked plasma chamber system comprising:
a plasma chamber, including a top electrode and a bottom electrode;
a plurality of RF sources, at least one of the plurality of RF sources being coupled to the bottom electrode;
a phase locking circuit coupled to at least two of the plurality of RF sources hereafter designated the first RF source and the second RF source; and
a controller coupled to the plasma chamber, each of the plurality of RF sources and the phase locking circuit, the controller including:
operating system software;
a plurality of logic circuits; and
a process recipe
wherein the operating system and logic circuits include:
logic for injecting a process gas into the plasma chamber;
logic for phase-locking a first RF signal and a second RF signal, wherein the second RF signal is a second harmonic of the first RF signal;
logic for coupling the phase-locked first RF signal and second RF signal to the plasma chamber;
logic for igniting a plasma in the plasma chamber;
logic for ejecting plasma ions from a lower plasma sheath with an increased energy when the phase-locked first RF signal and second RF signal peaks coincide.
